(19) United States
(12) Patent Application Publication
(10) Pub. No.: US 2020/0303273 A1
(43) Pub. Date: Sep. 24, 2020

(54) POWER MODULE

(71) Applicant: KABUSHIKI KAISHA TOSHIBA, Minato-ku (JP)

(72) Inventors: Haruka YAMAMOTO, Yokohama (JP); Michinobu INOUE, Yokohama (JP); Shinya HAYASHIYAMA, Tachikawa (JP)

(73) Assignee: KABUSHIKI KAISHA TOSHIBA, Minato-ku (JP)

(21) Appl. No.: 16/812,436

(22) Filed: Mar. 9, 2020

(30) Foreign Application Priority Data
Mar. 20, 2019 (JP) 2019-052340

(51) Int. Cl. H01L 23/24; H01L 23/053; H01L 23/10

(52) U.S. Cl. CPC H01L 23/24; H01L 23/10; H01L 23/053

(57) ABSTRACT

A power module includes a housing including an external terminal exposed at an outer surface of the housing, a substrate provided inside the housing, a semiconductor element mounted to the substrate, a wire connected to the semiconductor element, a metal plate terminal provided inside the housing, and a gel material provided inside the housing; the metal plate terminal connects the external terminal to an electrode of the semiconductor element; and the gel material covers the wire, the semiconductor element, the substrate, and a portion of the metal plate terminal. The metal plate terminal includes a first portion disposed inside the gel material between the wire and a top plate of the housing, a second portion bent with respect to the first portion and connected to the electrode of the semiconductor element, and a third portion extending from an end portion of the first portion toward the substrate.

### CROSS-REFERENCE TO RELATED APPLICATIONS

This application is based upon and claims the benefit of priority from the prior Japanese Patent Application No. 2019-052340, filed on Mar. 20, 2019; the entire contents of which are incorporated herein by reference.

### FIELD

Embodiments relate to a power module.

### BACKGROUND

Conventionally, a power module that controls a current has been developed, and includes a substrate fixed inside a housing, and power semiconductor elements mounted to the substrate; electrodes of the power semiconductor elements are drawn out of the housing by a metal plate terminal; and a gel material is filled into the housing. It is desirable for such a power module to have high reliability for the thermal load generated when repeatedly conducting/blocking.

### BRIEF DESCRIPTION OF THE DRAWINGS

FIG. 1 is a perspective view showing a power module according to a first embodiment;

FIG. 2 is a perspective cross-sectional view showing the power module according to the first embodiment;

FIG. 3 is a cross-sectional view showing the power module according to the first embodiment;

FIG. 4A is a cross-sectional view showing a room-temperature state of a power module according to a comparative example;

FIG. 4B is a cross-sectional view showing a high-temperature state of the power module according to the comparative example;

FIG. 4C is a cross-sectional view showing a high-temperature state of the power module according to the first embodiment;

FIG. 5 is a perspective view showing a power module according to a second embodiment;

FIG. 6 is a perspective cross-sectional view showing the power module according to the second embodiment;

FIG. 7A is a cross-sectional view showing a room-temperature state of the power module according to the second embodiment;

FIG. 7B is a cross-sectional view showing a high-temperature state of the power module according to the second embodiment;

FIG. 8 is a perspective exploded view showing a power module according to a third embodiment;

FIG. 9 is a perspective cross-sectional view showing the power module according to the third embodiment;

FIG. 10 is a cross-sectional view showing the operation of the power module according to the third embodiment;

FIG. 11 is a perspective exploded view showing a power module according to a fourth embodiment;

FIG. 12 is a perspective cross-sectional view showing the power module according to the fourth embodiment;

FIG. 13A is a perspective view showing the power module assumed in a first test example;

FIG. 13B shows an analysis model of the gel material;

FIG. 13C shows a strain distribution of the gel material;

FIG. 14 is a graph showing the effects of the height of the planar portion 33 on the strain amount of the gel material, in which the horizontal axis is a height h of the planar portion 33 of the metal plate terminal 30, and the vertical axis is the maximum value of the strain of the gel material;

FIG. 15A shows an analysis model of the gel material in the case where the partition plate is not provided;

FIG. 15B shows an analysis model of the gel material of the case where the partition plate is provided; and

FIG. 15C is a graph showing the effects of the existence or absence of the partition plate on the strain amount of the gel material, in which the horizontal axis is the existence or absence of the partition plate, and the vertical axis is the maximum value of the strain amount of the gel material.

### DETAILED DESCRIPTION

A power module according to an embodiment includes a housing including an external terminal exposed at an outer surface of the housing, a substrate provided inside the housing, a semiconductor element mounted to the substrate, a wire connected to the semiconductor element, a metal plate terminal provided inside the housing, and a gel material provided inside the housing; the metal plate terminal connects the external terminal to an electrode of the semiconductor element; and the gel material covers the wire, the semiconductor element, the substrate, and a portion of the metal plate terminal. The metal plate terminal includes a first portion disposed inside the gel material between the wire and a top plate of the housing, a second portion bent with respect to the first portion and connected to the electrode of the semiconductor element, and a third portion extending from an end portion of the first portion toward the substrate.

### First Embodiment

A first embodiment will now be described.

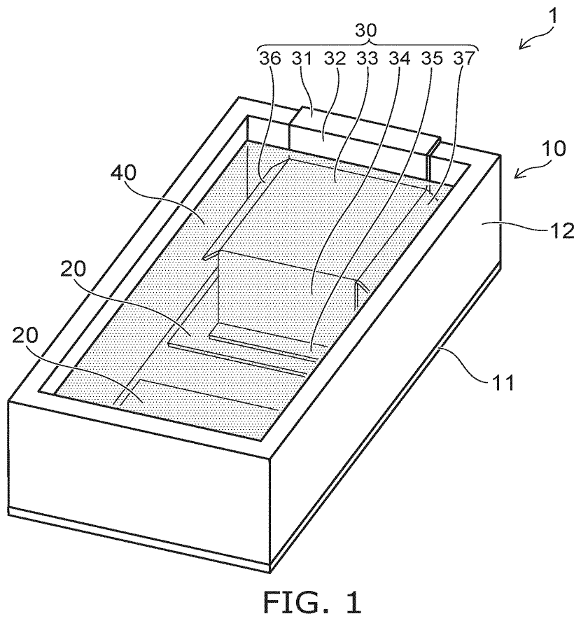

FIG. 1 is a perspective view showing a power module according to the embodiment.

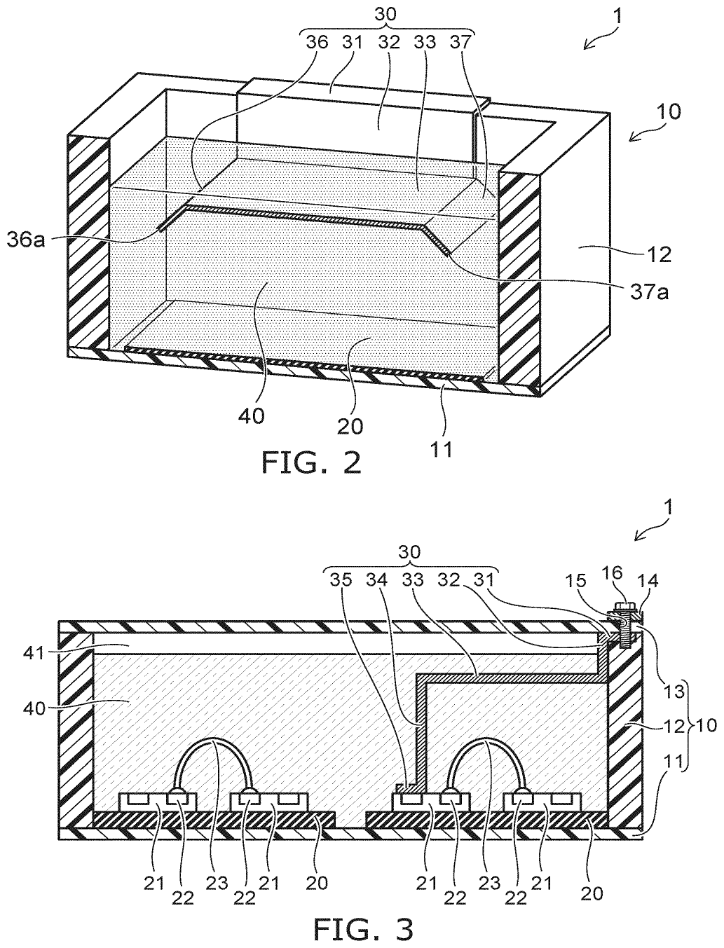

FIG. 2 is a perspective cross-sectional view showing the power module according to the embodiment.

FIG. 3 is a cross-sectional view showing the power module according to the embodiment.

The drawings are schematic; and the components are not illustrated or emphasized as appropriate. This is similar for the other drawings described below as well. For example, in FIG. 1 and FIG. 2, the top plate of the housing is not illustrated for convenience of illustration.

As shown in FIG. 1 to FIG. 3, a housing 10 is provided in the power module 1 according to the embodiment. For example, the housing 10 has a substantially rectangular parallelepiped configuration; and the interior is hollow. A bottom plate 11, a side plate 12, and a top plate 13 are provided in the housing 10. For example, the bottom plate 11 and the top plate 13 have rectangular flat plate configurations. For example, the side plate 12 has a quadrilateral tubular configuration.

Multiple external terminals 14 are provided at the top plate 13. The external terminals 14 are exposed at the outer surface of the housing 10. Through-holes 15 are formed to pierce the top plate 13 and the external terminals 14. Although the direction from the bottom plate 11 toward the top plate 13 is called “up” and the direction from the top plate 13 toward the bottom plate 11 is called “down” hereinbelow, these expressions are for convenience and are independent of the direction of gravity. “Up” and “down” also are generally referred to as the “vertical direction.”

For example, an insulative substrate 20 is provided on the bottom plate 11. Multiple semiconductor elements 21 are mounted on the upper surface of the substrate 20. The semiconductor element 21 is, for example, a power semiconductor element, e.g., a MOSFET (Metal-Oxide-Semiconductor Field-Effect Transistor), an IGBT (Insulated Gate Bipolar Transistor), a bipolar transistor, a diode, etc. The major semiconductor material that is used to form the semiconductor element 21 is, for example, silicon carbide (SiC) or silicon (Si). For example, two or three electrodes 22 are provided on each semiconductor element 21. Wires 23 are connected between the electrodes 22 of the different semiconductor elements 21. Loops are formed in the wires 23 above the semiconductor elements 21.

For example, three metal plate terminals 30 are provided inside the housing 10. Only one metal plate terminal 30 is illustrated in FIG. 1 to FIG. 3. The metal plate terminal 30 includes a metal and is made of, for example, copper (Cu). For example, the metal plate terminal 30 is formed by bending one metal plate.

Planar portions 31 to 37 are provided as one body in the metal plate terminal 30. The planar portions 31 to 35 are consecutively arranged in this order. The planar portion 31 is positioned between the side plate 12 and the top plate 13 of the housing 10 and is connected to the external terminals 14 via bolts 16 inserted into the through-holes 15. In the specification, a “connection” means an electrical connection.

The planar portion 32 is bent to extend downward from the end edge of the planar portion 31 inside the housing 10. The planar portion 33 is bent to extend in a direction (hereinbelow, called the “horizontal direction”) parallel to the upper surface of the substrate 20 from the lower end edge of the planar portion 32. The planar portion 34 extends downward from the end edge of the planar portion 33 at the side opposite to the boundary between the planar portion 33 and the planar portion 32. The planar portion 35 is bent to extend in the horizontal direction from the lower end edge of the planar portion 34 and is connected to the electrode 22 of the semiconductor element 21. Thus, the metal plate terminal 30 connects the external terminals 14 to the electrodes 22 of the semiconductor elements 21.

The planar portion 36 of the metal plate terminal 30 is bent to extend obliquely downward from one of the two end edges of the planar portion 33 other than the end edge continuous with the planar portion 32 and the end edge continuous with the planar portion 34. The tip of the planar portion 36 is a free end. Similarly, the planar portion 37 is bent to extend obliquely downward from the other of the two end edges described above. The tip of the planar portion 37 is a free end. For example, the planar portions 36 and 37 are tilted to extend away from each other downward.

The planar portions 36, 33, and 37 are consecutively arranged in this order. Therefore, the planar portion 32 that extends upward, the planar portion 36 that extends obliquely downward, the planar portion 34 that extends downward, and the planar portion 37 that extends obliquely downward are positioned in four mutually-orthogonal directions when viewed from the planar portion 33 spreading in the horizontal direction.

The wires 23 are disposed in the region directly under the planar portion 33, that is, between the substrate 20 and the planar portion 33. In other words, the planar portion 33 is disposed between the top plate 13 and the wires 23.

A gel material 40 is sealed inside the housing 10. The gel material 40 covers the substrate 20, the semiconductor elements 21, and the wires 23. The gel material 40 also covers the lower portion of the planar portion 32 of the metal plate terminal 30 and the entirety of each of the planar portions 33 to 37. The gel material 40 is insulative; and the elastic modulus of the gel material 40 is lower than the elastic modulus of a metal. The gel material 40 is made of, for example, a silicone gel. The breakage of the wires 23 due to thermal stress can be suppressed by the gel material 40. Also, the insulative properties between the metal plate terminals 30, between the wires 23, between the metal plate terminal 30 and the wires 23, etc., can be ensured by the gel material 40. Also, the substrate 20, the semiconductor elements 21, the wires 23, etc., are protected by the gel material 40 from oxygen, moisture, fine particles, etc., entering the housing 10 from the outside.

The gel material 40 does not fill the entire interior of the housing 10; and an air layer 41 exists on the gel material 40 inside the housing 10. The housing 10 is not in a perfectly airtight state; and the air of the air layer 41 can flow in and out of the housing 10. The gel material 40 deforms easily, but is a solid formed as one body and does not leak externally through gaps of the housing 10.

An operation of the power module according to the embodiment will now be described.

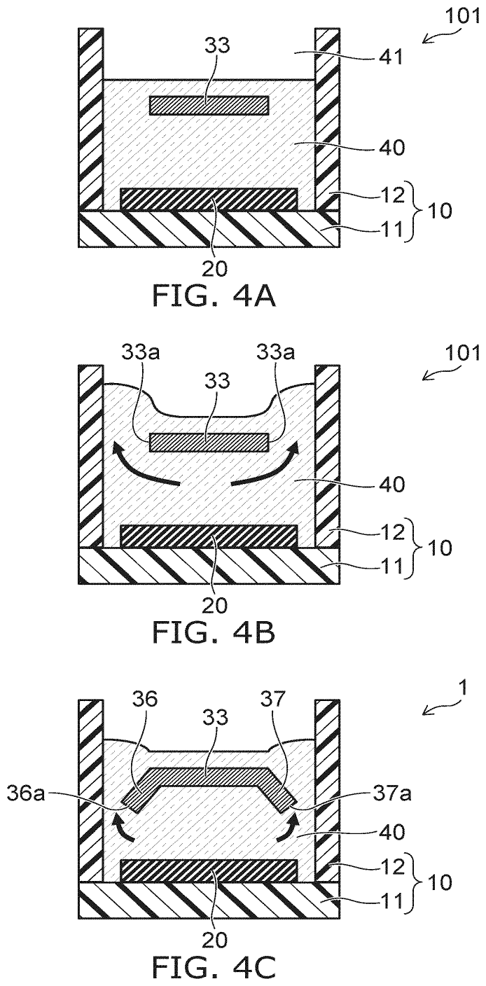

FIG. 4A is a cross-sectional view showing a room-temperature state of a power module according to a comparative example; FIG. 4B is a cross-sectional view showing a high-temperature state of the power module according to the comparative example; and FIG. 4C is a cross-sectional view showing a high-temperature state of the power module according to the embodiment.

When electrical power is supplied to the power module 1 and the semiconductor elements 21 conduct, the semiconductor elements 21 generate heat; and the temperature of the entire power module 1 rises. Accordingly, each member of the power module 1 undergoes thermal expansion; but the thermal expansion coefficient is different between the members. The thermal expansion coefficient of the gel material 40 is larger than the thermal expansion coefficient of the housing 10 and the thermal expansion coefficient of the metal plate terminal 30. Therefore, when the temperature of the power module 1 rises, the increase rate of the volume of the gel material 40 becomes larger than the increase rate of the volume of the housing 10; and the upper surface of the gel material 40 rises. When the conduction of the power module 1 stops, the temperature of the power module 1 decreases from the high temperature to room temperature. Thereby, the volume of the gel material 40 decreases; and the upper surface of the gel material 40 drops.

In the power module 101 according to the comparative example as shown in FIGS. 4A and 4B, the planar portions 36 and 37 are not provided in the metal plate terminal 30. Therefore, when the temperature of the power module 101 rises, the gel material 40 moves upward while contacting end portions 33a of the planar portion 33 of the metal plate terminal 30. At this time, a large shear force is applied from the end portions 33a of the planar portion 33 to the gel material 40. When the temperature of the power module 101 decreases, the gel material 40 moves downward while contacting the end portions 33a of the planar portion 33 of the metal plate terminal 30.

Thus, as the heating and the cooling of the power module 101 repeats as the power module 101 operates, a shear force is repeatedly applied to the gel material 40; and cracks occur in the gel material 40. As a result, the support effect of the wires 23, the insulation effect of the metal plate terminals 30 and the wires 23, and the protection effect from the external environment which are provided by the gel material 40 decrease; the likelihood of dielectric breakdown occurring between the metal plate terminals 30 increases; and the reliability of the power module 101 undesirably decreases.

Conversely, in the power module 1 according to the embodiment as shown in FIG. 4C, the planar portions 36 and 37 are provided in the metal plate terminal 30. Therefore, when the temperature of the power module 1 changes, the gel material 40 moves vertically while contacting an end portion 36a of the planar portion 36 and an end portion 37a of the planar portion 37 without contacting the end portions 33a of the planar portion 33. The movement amount of the gel material 40 when heating and cooling is dependent on the position in the vertical direction; and the movement amount is smaller for the gel material 40 positioned lower, that is, proximal to the bottom plate 11. Also, the end portions 36a and 37a are positioned lower than the end portions 33a. Therefore, the movement amount of the gel material 40 moving while contacting the end portions 36a and 37a in the power module 1 is smaller than the movement amount of the gel material 40 moving while contacting the end portions 33a in the power module 101.

Accordingly, compared to the comparative example, the shear force that is applied to the gel material 40 by the metal plate terminal 30 is small in the embodiment. Therefore, in the power module 1, the occurrence of the cracks in the gel material 40 can be suppressed. As a result, the reliability of the power module 1 according to the embodiment is high.

By disposing the planar portion 33 at a constant height in the power module 1 according to the embodiment, a space for forming the loops of the wires 23 can be ensured between the substrate 20 and the planar portion 33. Therefore, contacting and shorting of the wires 23 to the planar portion 33 can be prevented.

### Second Embodiment

A second embodiment will now be described.

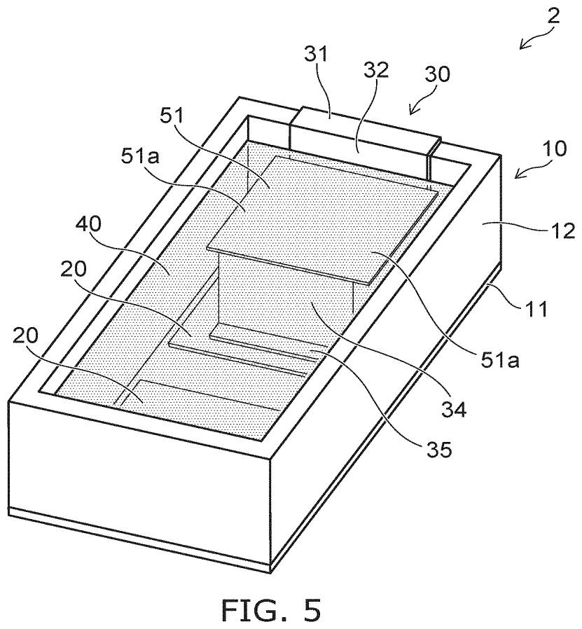

FIG. 5 is a perspective view showing a power module according to the embodiment.

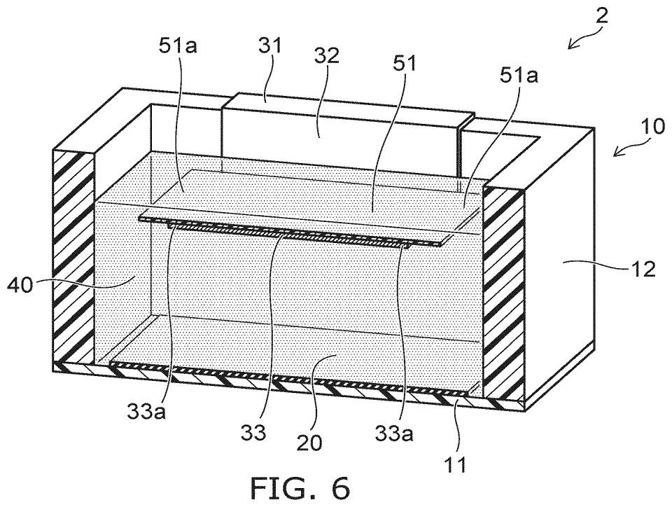

FIG. 6 is a perspective cross-sectional view showing the power module according to the embodiment.

As shown in FIG. 5 and FIG. 6, the power module 2 according to the embodiment differs from the power module 1 according to the first embodiment (referring to FIG. 1 to FIG. 3) in that the planar portions 36 and 37 are not provided in the metal plate terminal 30; and a low-rigidity plate 51 is provided on the planar portion 33 of the metal plate terminal 30.

The rigidity of the low-rigidity plate 51 is lower than the rigidity of the planar portion 33 of the metal plate terminal 30. For example, the Young's modulus of the material of the low-rigidity plate 51 is lower than the Young's modulus of the material of the metal plate terminal 30. The low-rigidity plate 51 is made of, for example, a resin material and is made of, for example, PET (PolyEthylene Terephthalate).

For example, the low-rigidity plate 51 is bonded to the upper surface of the planar portion 33 of the metal plate terminal 30 by bonding, fastening by bolts, etc. When viewed from above, the low-rigidity plate 51 is larger than the planar portion 33; and end portions 51a of the low-rigidity plate 51 jut from the end portions 33a of the planar portion 33.

An operation of the power module according to the embodiment will now be described.

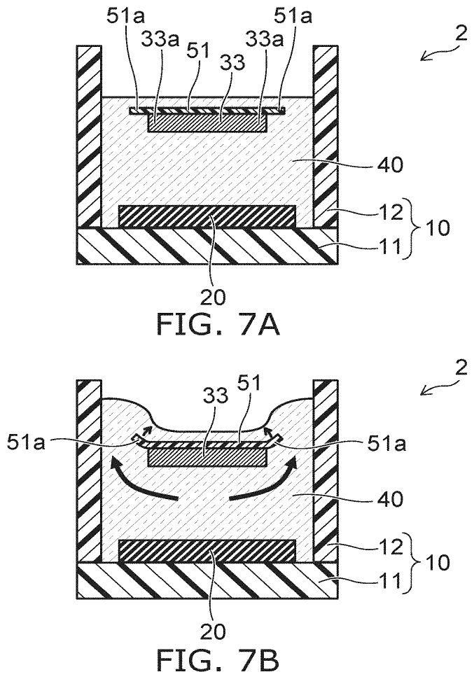

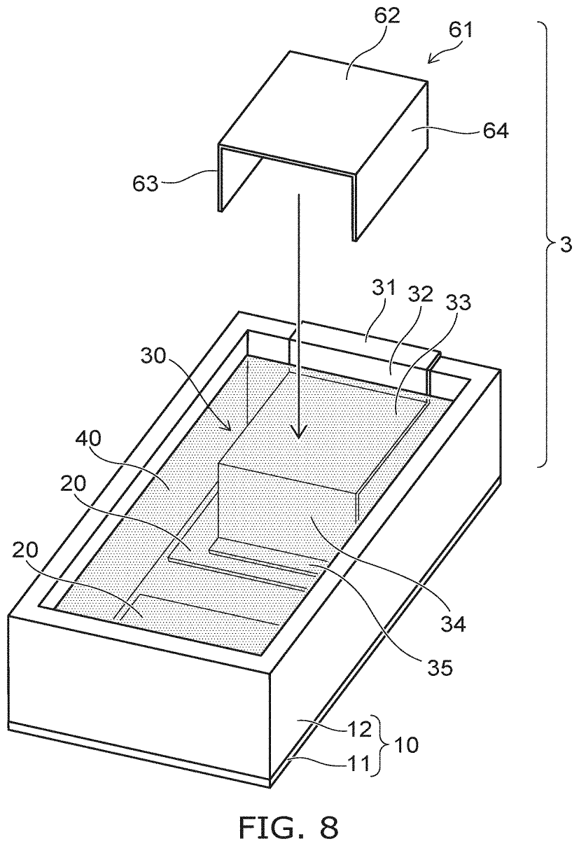

FIG. 7A is a cross-sectional view showing a room-temperature state of the power module according to the embodiment; and FIG. 7B is a cross-sectional view showing a high-temperature state of the power module according to the embodiment.

As described above, when viewed from above in the power module 2, the end portions 51a of the low-rigidity plate 51 jut from the end portions 33a of the planar portion 33. Therefore, when the gel material 40 moves vertically due to the thermal cycles, the gel material 40 moves to flow around the end portions 51a of the low-rigidity plate 51 without flowing around the end portions 33a of the planar portion 33.

As shown in FIGS. 7A and 7B, because the rigidity of the low-rigidity plate 51 is lower than that of the planar portion 33 of the metal plate terminal 30, the low-rigidity plate 51 deforms to somewhat follow the movement of the gel material 40. Thereby, the end portions 51a of the low-rigidity plate 51 can relax the shear force applied to the gel material 40. As a result, the occurrence of the cracks in the gel material 40 can be suppressed. Thereby, the reliability of the power module 2 according to the embodiment is high.

The material of the low-rigidity plate 51 may be the same as the material of the metal plate terminal 30; and the thickness of the low-rigidity plate 51 may be thinner than the thickness of the planar portion 33 of the metal plate terminal 30. The rigidity of the low-rigidity plate 51 is caused to be lower than the rigidity of the planar portion 33 thereby; and the effects described above can be obtained. The low-rigidity plate 51 may be bonded to the lower surface of the planar portion 33.

Otherwise, the configuration, the operations, and the effects of the embodiment are similar to those of the first embodiment.

### Third Embodiment

A third embodiment will now be described.

FIG. 8 is a perspective exploded view showing a power module according to the embodiment.

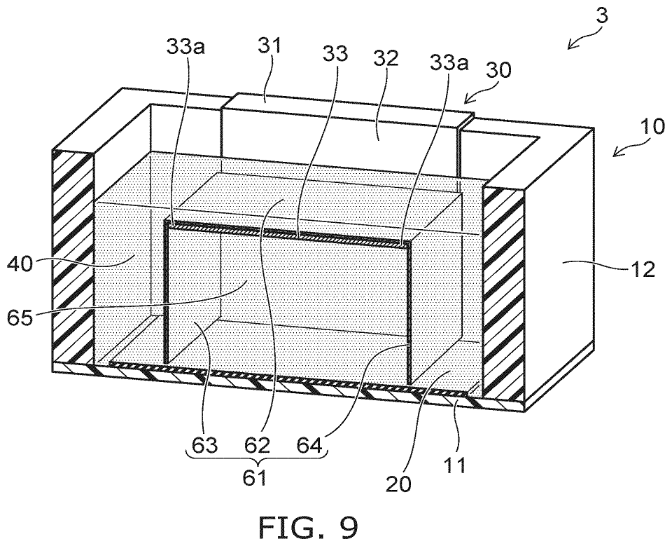

FIG. 9 is a perspective cross-sectional view showing the power module according to the embodiment.

As shown in FIG. 8 and FIG. 9, the power module 3 according to the embodiment differs from the power module 1 according to the first embodiment (referring to FIG. 1 to FIG. 3) in that the planar portions 36 and 37 are not provided in the metal plate terminal 30; and a partition plate 61 is provided to cover the planar portion 33 of the metal plate terminal 30 and the region directly under the planar portion 33.

It is favorable for the partition plate 61 to be made of an insulating material; and the partition plate 61 is made of, for example, a resin material. The partition plate 61 has a configuration in which one rectangular plate is bent into a C-shape. More specifically, vertical portions 63 and 64 that extend downward from two sides of a horizontal portion 62 are provided as one body with the horizontal portion 62 in the partition plate 61.

For example, the horizontal portion 62 is bonded to the upper surface of the planar portion 33 of the metal plate terminal 30 by fixing by a bonding agent, an adhesive sheet, fastening by bolts, etc. When viewed from above, the configuration of the horizontal portion 62 is substantially the same as the configuration of the planar portion 33 or slightly larger. The vertical portions 63 and 64 are bent from the horizontal portion 62 to cover the end portions 33a at the two sides of the planar portion 33. For example, the lower ends of the vertical portions 63 and 64 do not reach the substrate 20. A space 65 between the planar portion 33 and the substrate 20 is partitioned from the periphery by the planar portions 33 and 34 of the metal plate terminal 30, the vertical portions 63 and 64 of the partition plate 61, and a portion of the side plate 12 of the housing 10.

An operation and effects of the power module according to the embodiment will now be described.

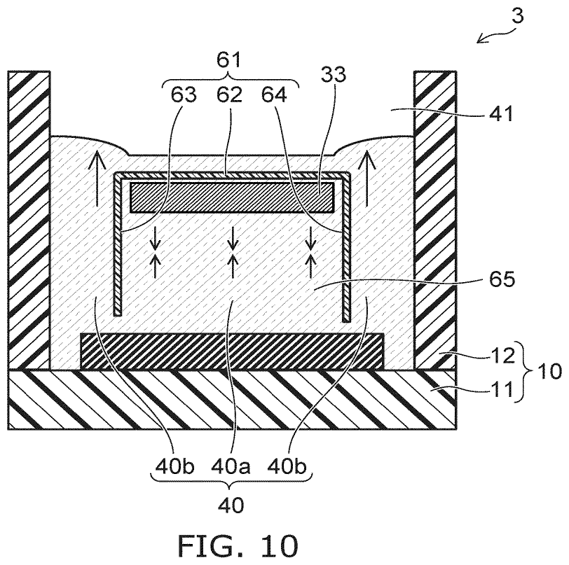

FIG. 10 is a cross-sectional view showing the operation of the power module according to the embodiment.

In the embodiment as shown in FIG. 10, the space 65 is partitioned by the planar portions 33 and 34 of the metal plate terminal 30, the vertical portions 63 and 64 of the partition plate 61, and a portion of the side plate 12 of the housing 10. Therefore, a portion 40a of the gel material 40 disposed inside the space 65 and portions 40b of the gel material 40 disposed outside the space 65 are substantially isolated and move separately due to the thermal cycles.

In other words, when the power module 3 is heated, the gel material 40 expands; but the planar portions 33 and 34, the vertical portions 63 and 64, and the side plate 12 impede the upward movement of the portion 40a of the gel material 40 disposed inside the space 65. On the other hand, the portions 40b of the gel material 40 disposed outside the space 65 move upward along the surfaces of the vertical portions 63 and 64 of the partition plate 61. At this time, the vertical portions 63 and 64 are substantially not interposed in the movement path of the portions 40b; therefore, the vertical portions 63 and 64 substantially do not apply shear forces to the portions 40b of the gel material 40. Therefore, the occurrence of the cracks in the gel material 40 can be suppressed.

Because the partition plate 61 is insulative, shorts do not occur even when the partition plate 61 contacts the wires 23 and the electrodes 22 of the semiconductor elements 21.

The horizontal portion 62 of the partition plate 61 may be adhered to the lower surface of the planar portion 33 of the metal plate terminal 30.

Otherwise, the configuration, the operations, and the effects of the embodiment are similar to those of the first embodiment.

### Fourth Embodiment

A fourth embodiment will now be described.

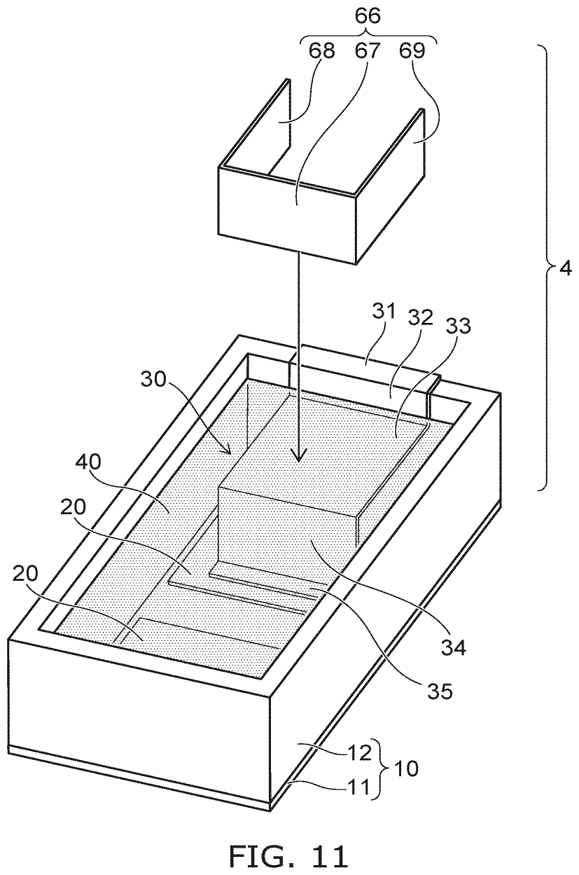

FIG. 11 is a perspective exploded view showing a power module according to the embodiment.

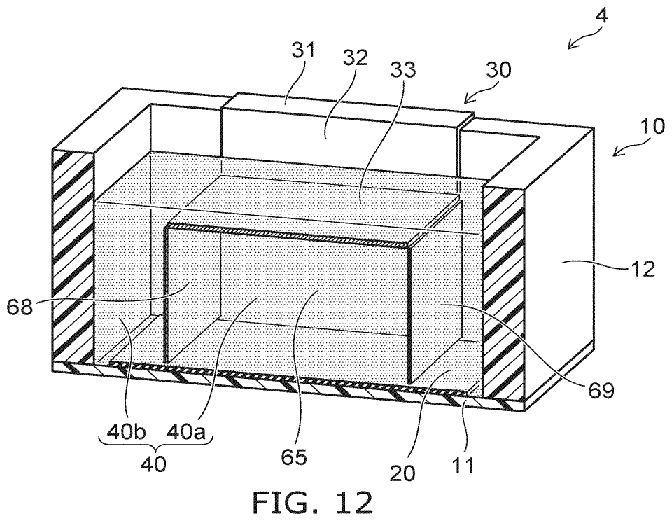

FIG. 12 is a perspective cross-sectional view showing the power module according to the embodiment.

As shown in FIG. 11 and FIG. 12, the power module 4 according to the embodiment differs from the power module 3 according to the third embodiment (referring to FIG. 8 to FIG. 10) in that a partition plate 66 is provided instead of the partition plate 61.

Similarly to the partition plate 61, it is favorable for the partition plate 66 to be made of an insulating material; and the partition plate 66 is made of, for example, a resin material. Although the partition plate 66 also has a configuration in which one rectangular plate is bent into a C-shape, the direction of the bend is different from that of the partition plate 61. Vertical portions 67, 68, and 69 are provided as one body in the partition plate 66.

For example, the vertical portion 67 of the partition plate 66 is bonded to the surface of the planar portion 34 of the metal plate terminal 30 at the side opposite to the planar portion 33 by being fixed by a bonding agent, an adhesive sheet, fastening by bolts, etc. For example, the lower end of the vertical portion 67 does not reach the substrate 20. The vertical portions 68 and 69 are bent from the two horizontal-direction end portions of the vertical portion 67 toward the planar portion 32. A space that corresponds to the region directly under the planar portion 33 of the metal plate terminal 30, i.e., the space 65 between the planar portion 33 and the substrate 20, is partitioned from the periphery by the planar portions 33 and 34 of the metal plate terminal 30, the vertical portions 68 and 69 of the partition plate 66, and a portion of the side plate 12 of the housing 10.

The vertical portion 67 of the partition plate 66 may be bonded to the surface of the planar portion 34 of the metal plate terminal 30 at the planar portion 33 side.

Otherwise, the configuration, the operations, and the effects of the embodiment are similar to those of the third embodiment.

### First Test Example

A first test example will now be described.

In the test example, the effects of the height of the planar portion 33 of the metal plate terminal 30, i.e., the distance from the bottom plate 11, on the strain of the gel material 40 were verified.

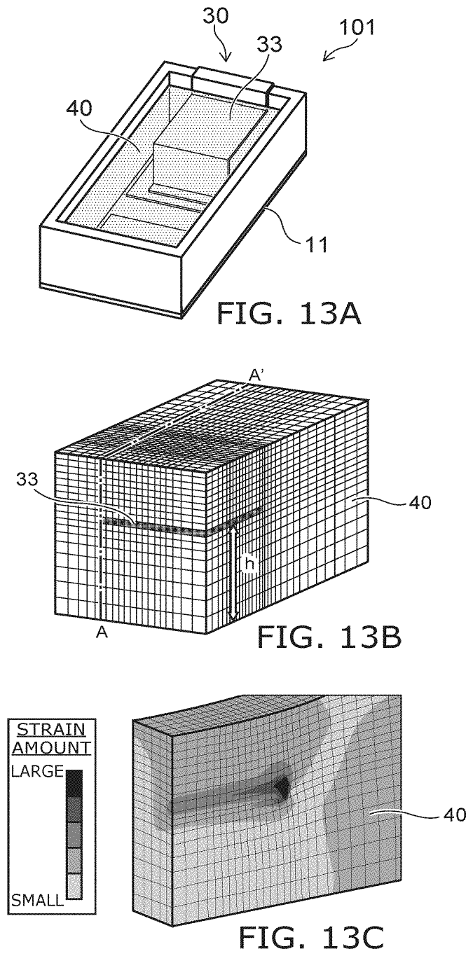

FIG. 13A is a perspective view showing the power module assumed in the test example; FIG. 13B shows the analysis model of the gel material; and FIG. 13C shows the strain distribution of the gel material. The portion shown in FIG. 13C corresponds to an A-A′ cross section of FIG. 13B.

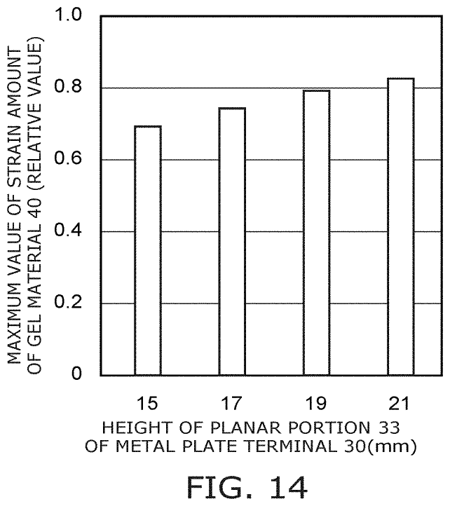

FIG. 14 is a graph showing the effects of the height of the planar portion 33 on the strain amount of the gel material 40, in which the horizontal axis is a height h of the planar portion 33 of the metal plate terminal 30, and the vertical axis is the maximum value of the strain of the gel material.

As shown in FIG. 13A, the configuration of the power module assumed in the test example is the same as the configuration of the power module 101 according to the comparative example shown in FIG. 4A in which the planar portions 36 and 37 of the metal plate terminal 30 are excluded from the power module 1 according to the first embodiment.

The strain that is generated in each portion of the gel material 40 for the power module 101 shown in FIG. 13A was simulated for when the gel material 40 undergoes thermal expansion as shown in FIG. 13B. As a result, as shown in FIG. 13C, the strain of the gel material 40 had a maximum at the end portion vicinity of the planar portion 33.

Such a simulation was performed multiple times for different heights of the planar portion 33. As shown in FIG. 14, the maximum value of the strain amount decreased as the height of the planar portion 33 was reduced. Therefore, it was confirmed that the strain amount of the gel material 40 can be reduced by providing the planar portions 36 and 37 in the metal plate terminal 30 and by lowering the positions of the end portion 36a of the planar portion 36 and the end portion 37a of the planar portion 37 as in the first embodiment. It is considered that the likelihood of cracks occurring in the gel material 40 is reduced by reducing the strain amount of the gel material 40.

### Second Test Example

A second test example will now be described.

In the test example, the effects of the existence of the partition plate in the third and fourth embodiments on the strain of the gel material was verified.

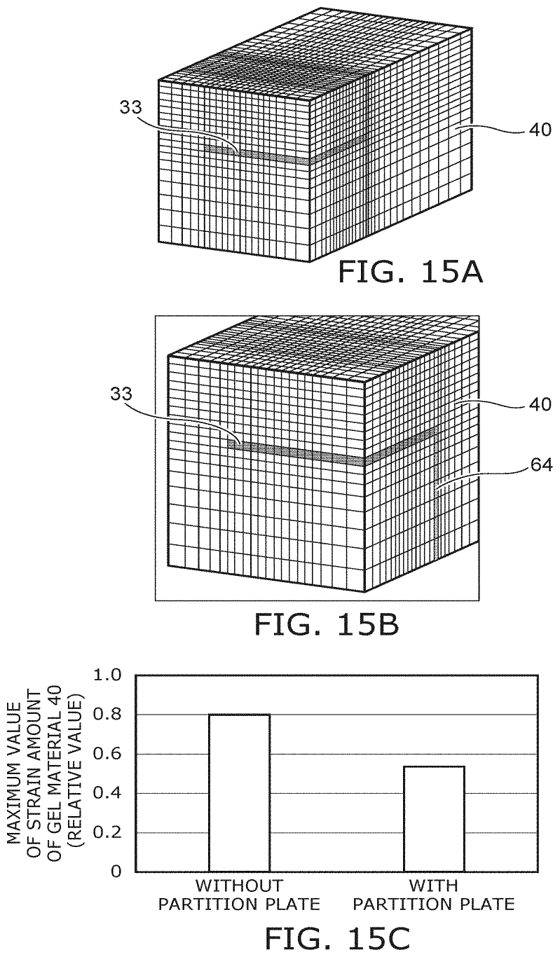

FIG. 15A shows an analysis model of the gel material in the case where the partition plate is not provided; FIG. 15B shows the analysis model of the gel material of the case where the partition plate is provided; and FIG. 15C is a graph showing the effects of the existence or absence of the partition plate on the strain amount of the gel material, in which the horizontal axis is the existence or absence of the partition plate, and the vertical axis is the maximum value of the strain amount of the gel material.

The model shown in FIG. 15A assumes the power module 101 according to the comparative example described above. The model shown in FIG. 15B assumes the power module 3 according to the third embodiment and the power module 4 according to the fourth embodiment described above.

As shown in FIGS. 15A and 15B, the distribution of the strain generated in the gel material 40 when the gel material 40 undergoes thermal expansion was simulated for the cases with and without the partition plate. As a result, as shown in FIG. 15C, the maximum value of the strain amount of the gel material 40 was lower for the case where the partition plate is provided than for the case where the partition plate is not provided. It is therefore considered that compared to the power module 101 according to the comparative example, in the power module 3 according to the third embodiment and the power module 4 according to the fourth embodiment, the strain amount of the gel material 40 is low; and the likelihood of cracks occurring in the gel material 40 is low.

According to the embodiments described above, a power module that has high reliability can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power module, comprising:
a housing including an external terminal exposed at an outer surface of the housing;
a substrate provided inside the housing;
a semiconductor element mounted to the substrate;
a wire connected to the semiconductor element;
a metal plate terminal provided inside the housing, the metal plate terminal connecting the external terminal to an electrode of the semiconductor element; and
a gel material provided inside the housing, the gel material covering the wire, the semiconductor element, the substrate, and a portion of the metal plate terminal,
the metal plate terminal including
a first portion disposed inside the gel material between the wire and a top plate of the housing,
a second portion bent with respect to the first portion and connected to the electrode of the semiconductor element, and
a third portion extending from an end portion of the first portion toward the substrate.

2. A power module, comprising:
a housing including an external terminal exposed at an outer surface of the housing;
a substrate provided inside the housing;
a semiconductor element mounted to the substrate;
a wire connected to the semiconductor element;
a metal plate terminal provided inside the housing, the metal plate terminal connecting the external terminal to an electrode of the semiconductor element;
a low-rigidity plate; and
a gel material provided inside the housing, the gel material covering the wire, the semiconductor element, the substrate, the low-rigidity plate, and a portion of the metal plate terminal,
the metal plate terminal including
a first portion disposed inside the gel material between the wire and a top plate of the housing, and
a second portion bent with respect to the first portion and connected to the electrode of the semiconductor element,
a rigidity of the low-rigidity plate being lower than a rigidity of the first portion,
the low-rigidity plate being bonded to the first portion,
an end portion of the low-rigidity plate jutting from an end portion of the first portion.

3. The module according to claim 2, wherein the low-rigidity plate is made of a resin material.

4. A power module, comprising:
a housing including an external terminal exposed at an outer surface of the housing;
a substrate provided inside the housing;
a semiconductor element mounted to the substrate;
a wire connected to the semiconductor element;
a metal plate terminal provided inside the housing, the metal plate terminal connecting the external terminal to an electrode of the semiconductor element;
a partition plate provided inside the housing; and
a gel material provided inside the housing, the gel material covering the wire, the semiconductor element, the substrate, the partition plate, and a portion of the metal plate terminal,
the metal plate terminal including
a first portion disposed inside the gel material between the wire and a top plate of the housing, and
a second portion bent with respect to the first portion and connected to the electrode of the semiconductor element,
the partition plate, the metal plate terminal, and a portion of the housing partitioning a space from a periphery, the space being between the first portion and the substrate.

5. The module according to claim 4, wherein a portion of the partition plate is bonded to the first portion.

6. The module according to claim 4, wherein a portion of the partition plate is bonded to the second portion.

7. The module according to claim 4, wherein the partition plate is made of a resin material.
